(19) United States
(12) Patent Application Publication
(10) Pub. No.: US 2017/0285748 A1
(43) Pub. Date: Oct. 5, 2017

(54) LOCALIZED HAPTIC FEEDBACK BY ELECTRONIC DEVICES

(71) Applicant: Essential Products, Inc., Palo Alto, CA (US)

(72) Inventors: David John Evans, V, Palo Alto, CA (US); Xinrui Jiang, San Jose, CA (US); Andrew E. Rubin, Los Altos, CA (US); Matthew Hershenson, Los Altos, CA (US); Xiaoyu Miao, Palo Alto, CA (US); Joseph Anthony Tate, San Jose, CA (US); Jason Sean Gagne-Keats, Cupertino, CA (US)

(21) Appl. No.: 15/455,016

(22) Filed: Mar. 9, 2017

Related U.S. Application Data
(60) Provisional application No. 62/318,137, filed on Apr. 4, 2016.

(51) Int. Cl. G06F 3/01; B06B 1/06; H01L 41/09; H01L 41/187; G06F 3/041; G02F 1/1333

(52) U.S. Cl. CPC G06F 3/016; G06F 3/0416; G06F 3/0412; G02F 1/13338; H01L 41/09; H01L 41/1876; B06B 1/0607; G06F 2203/04105; G02F 2001/133302

(57) ABSTRACT

Various embodiments concern electronic devices capable of providing localized haptic feedback. More specifically, an electronic device can include an array of piezoelectric actuators that is disposed within the housing of the electronic device. When a user interacts with the electronic device (e.g., with content presented on a display), one or more of the piezoelectric actuators in the array can be induced into performing a haptic event. For example, a power source may selectively apply voltage to one or more piezoelectric actuators (and thus induce the haptic event). The localized haptic feedback provided by the piezoelectric actuator(s) can increase the realism of content experienced by the user.

### CROSS-REFERENCE TO RELATED APPLICATIONS

This application claims priority to and the benefit of U.S. Provisional Application 62/300,631, entitled “MOBILE DEVICES AND MOBILE DEVICE ACCESSORIES” (Attorney Docket No. 119306-8020.US00) filed on Feb. 26, 2016, and U.S. Provisional Application 62/318,137, entitled “LOCALIZED HAPTIC FEEDBACK BY ELECTRONIC DEVICES” (Attorney Docket No. 119306-8016.US00) filed on Apr. 4, 2016, each of which applications are included in their entirety by this reference hereto.

### RELATED FIELD

Various embodiments relate generally to electronic devices that perform haptic events. More specifically, various embodiments relate to electronic devices having multiple actuators capable of providing localized haptic feedback.

### BACKGROUND

Electronic devices often recreate a user's sense of touch by performing events that cause forces or vibrations to be applied to the user. These events, which support and enable haptic or kinesthetic communication, can be used to enhance the user's ability to remotely control an electronic device, improve the realism of virtual objects in computer simulations, etc. Many haptic devices incorporate tactile sensors that measure the forces exerted by the user on the electronic device.

Different haptic technologies are commonly found in many electronic devices. For example, this may take the form of a vibration in response to a touch event (i.e., a user interaction with the interface of an electronic device) or when a certain event occurs (e.g., an email or text message is received).

Electronic devices have conventionally included a single actuator that is responsible for performing the haptic events. Therefore, the force or vibration corresponding to a haptic event always originates from the same location, regardless of which type of haptic event is performed (e.g., different counts/durations of taps and vibrations).

### SUMMARY

Systems and techniques for providing localized haptic feedback by an electronic device are described herein. More specifically, an array of piezoelectric actuators can be disposed beneath the display of the electronic device. When a user interacts with content presented on the display (e.g., by touching the display), one or more of the piezoelectric actuators in the array can be induced into performing a haptic event.

For example, a power source may apply voltage to the piezoelectric actuator(s) (and thus induce the haptic event) when the user is watching a cinematic video, interacting with an application, or playing a video game. In some embodiments, a haptic processor that is communicatively coupled to touch circuitry within the electronic device is responsible for specifying how much voltage should be applied to each piezoelectric actuator by the power source. Consequently, touch events performed on the user device may affect which haptic event(s) are performed by the array of piezoelectric actuators. The localized haptic feedback provided by the piezoelectric actuator(s) can increase the realism of content experienced by the user.

The piezoelectric actuator(s) can be induced into performing the same haptic event or different types of haptic events. For example, the piezoelectric actuators disposed near the outer border of the display may vibrate periodically at a high intensity, while the piezoelectric actuators near in middle of the display may vibrate continuously at a low intensity.

### BRIEF DESCRIPTION OF THE DRAWINGS

One or more embodiments of the present invention are illustrated by way of example and not limitation in the figures of the accompanying drawings, in which like references indicate similar elements.

FIG. 1 depicts a user device that includes a haptic actuator disposed within a housing beneath a display.

FIG. 2 is an exploded perspective view of a conventional display assembly for a user device.

FIG. 3 is a side view of user device that illustrates how a haptic actuator is conventionally disposed beneath a portion of the display assembly.

FIG. 4 is an exploded perspective view of a display assembly for a user device that includes an array of piezoelectric actuators capable of providing localized haptic feedback.

FIG. 5 is a side view of a user device that illustrates how the array of piezoelectric actuators can be disposed beneath some or all of the display assembly.

FIG. 6 depicts an array of piezoelectric actuators that includes multiple zones having different actuator densities.

FIG. 7 depicts a process for providing localized haptic feedback by a user device.

FIG. 8 depicts a process for manufacturing a user device that includes an array of piezoelectric actuators, which are capable of providing localized haptic feedback.

FIG. 9 is a block diagram illustrating an example of a processing system in which at least some operations described herein can be implemented.

### DETAILED DESCRIPTION

Systems and techniques for providing localized haptic feedback by an electronic device are described herein. More specifically, an array of piezoelectric actuators can be disposed within or beneath the display assembly of the electronic device. The piezoelectric actuators may be able to perform different types of haptic events based on what content is being shown by the electronic device, in response to a user interaction with the electronic device, etc.

These techniques can be used with any electronic device (also referred to herein as a “user device”) for which it is desirable to provide more realistic and targeted haptic feedback, such as personal computers, tablets, personal digital assistants (PDAs), mobile phones, game consoles and controllers (e.g., Sony PlayStation or Microsoft Xbox), mobile gaming devices (e.g., Sony PSP or Nintendo 3DS), music players (e.g., Apple iPod Touch), wearable electronic devices (e.g., watches), network-connected (“smart”) devices (e.g., televisions), virtual/augmented reality systems and controllers (e.g., Oculus Rift or Microsoft Hololens), wearable devices (e.g., watches and fitness bands), and other portable electronic devices.

### Terminology

Brief definitions of terms, abbreviations, and phrases used throughout this application are given below.

Reference in this specification to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments necessarily mutually exclusive of other embodiments. Moreover, various features are described that may be exhibited by some embodiments and not by others. Similarly, various requirements are described that may be requirements for some embodiments and not for other embodiments.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof, means any connection or coupling, either direct or indirect, between two or more elements; the coupling of or connection between the elements can be physical, logical, or a combination thereof. For example, two components may be coupled directly to one another or via one or more intermediary channels or components. As another example, devices may be coupled in such a way that information can be passed there between, while not sharing any physical connection with one another. Additionally, the words “herein,” “above,” “below,” and words of similar import, when used in this application, shall refer to this application as a whole and not to any particular portions of this application. Where the context permits, words in the Detailed Description using the singular or plural number may also include the plural or singular number respectively. The word “or,” in reference to a list of two or more items, covers all of the following interpretations of the word: any of the items in the list, all of the items in the list, and any combination of the items in the list.

If the specification states a component or feature “may,” “can,” “could,” or “might” be included or have a characteristic, that particular component or feature is not required to be included or have the characteristic.

The term “module” refers broadly to software, hardware, or firmware components. Modules are typically functional components that can generate useful data or other output using specified input(s). A module may or may not be self-contained. An application program (also called an “application”) may include one or more modules, or a module can include one or more application programs.

The terminology used in the Detailed Description is intended to be interpreted in its broadest reasonable manner, even though it is being used in conjunction with certain examples. The terms used in this specification generally have their ordinary meanings in the art, within the context of the disclosure, and in the specific context where each term is used. For convenience, certain terms may be highlighted, for example using capitalization, italics, and/or quotation marks. The use of highlighting has no influence on the scope and meaning of a term; the scope and meaning of a term is the same, in the same context, whether or not it is highlighted. It will be appreciated that an element or feature can be described in more than one way.

Consequently, alternative language and synonyms may be used for any one or more of the terms discussed herein, and special significance is not to be placed on whether or not a term is elaborated or discussed herein. Synonyms for certain terms are provided. A recital of one or more synonyms does not exclude the use of other synonyms. The use of examples anywhere in this specification, including examples of any terms discussed herein, is illustrative only, and is not intended to further limit the scope and meaning of the disclosure or of any exemplified term. Likewise, the disclosure is not limited to the various embodiments given in this specification.

### System Overview

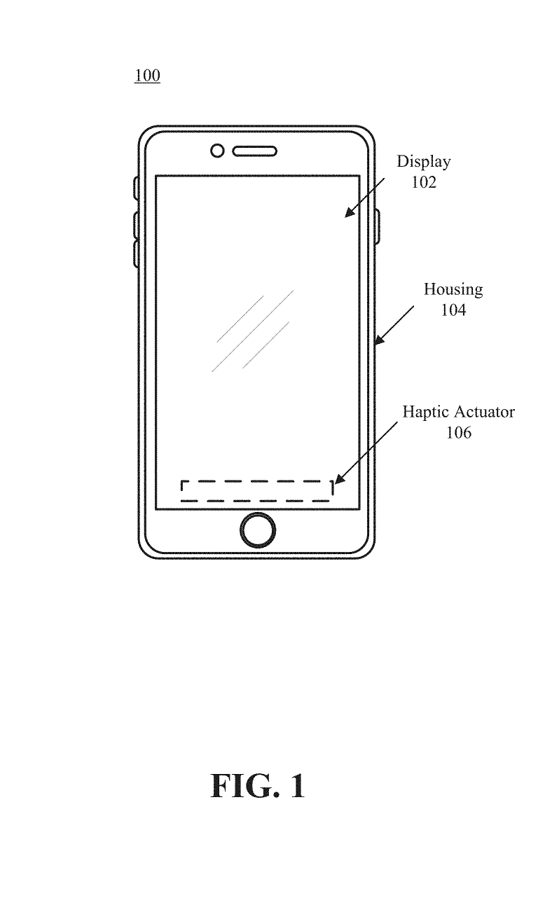

FIG. 1 depicts a user device 100 that includes a haptic actuator 106 disposed within a housing 104 beneath a display 102. The housing 104 also protects other components (e.g., sensors, connectors, power supply) that reside within the user device 100. The housing 104 is typically composed of a protective substrate, such as metal or plastic. In some embodiments, the display 102 is touch sensitive and is configured to generate signals responsive to a user contacting the outer surface of the display 102.

The user device could include other features as well, such as a camera, speaker, and a touch-sensitive button that are offset from the display 102. The camera, speaker, and/or touch-sensitive button may be located within an opaque border that surrounds the display 102 and is not responsive to user interactions (i.e., is not touch sensitive). The opaque border is often used to hide the various components that reside within the user device 100.

The haptic actuator 106 can provide tactile feedback in real time in the form of taps, vibrations, etc. (which are collectively referred to as “haptic events”). The type of haptic event performed by the haptic actuator 106 may correspond to how hard a user presses the display 102, where the user presses the display 102, etc. The haptic actuator 106 can be any kind of mechanical component that is capable of performing a haptic event. For example, the haptic actuator 106 may be a small motor that is driven by a processor and is electrically coupled to a rechargeable power supply disposed within the housing 104.

As shown in FIG. 1, conventional user devices include a single haptic actuator 106 that is responsible for providing haptic feedback. But such a configuration often limits the realism of the haptic feedback provided by the user device. Here, for example, the haptic feedback originates from the haptic actuator 106 regardless of whether the user interacts with the display 102 directly over the haptic actuator 106 or along the upper edge of the display 102 (although the strength and/or type of haptic event performed by the haptic actuator 106 may differ). Said another way, the conventional user device 100 is unable to provide localized haptic feedback because all haptic events are performed by a single haptic actuator 106 whose disposition within the housing 104 never changes.

Although FIG. 1 includes an illustration of a mobile phone, the techniques described herein can also be used with other electronic devices for which it is desirable to have localized haptic feedback. For example, the same techniques could be utilized with personal computers, tablets, personal digital assistants (PDAs), mobile phones, game consoles and controllers (e.g., Sony Play Station or Microsoft Xbox), mobile gaming devices (e.g., Sony PSP or Nintendo 3DS), music players (e.g., Apple iPod Touch), wearable electronic devices (e.g., watches), network-connected (“smart”) devices (e.g., televisions), virtual/augmented reality systems and controllers (e.g., Oculus Rift or Microsoft Hololens), wearable devices (e.g., watches and fitness bands), and other portable electronic devices.

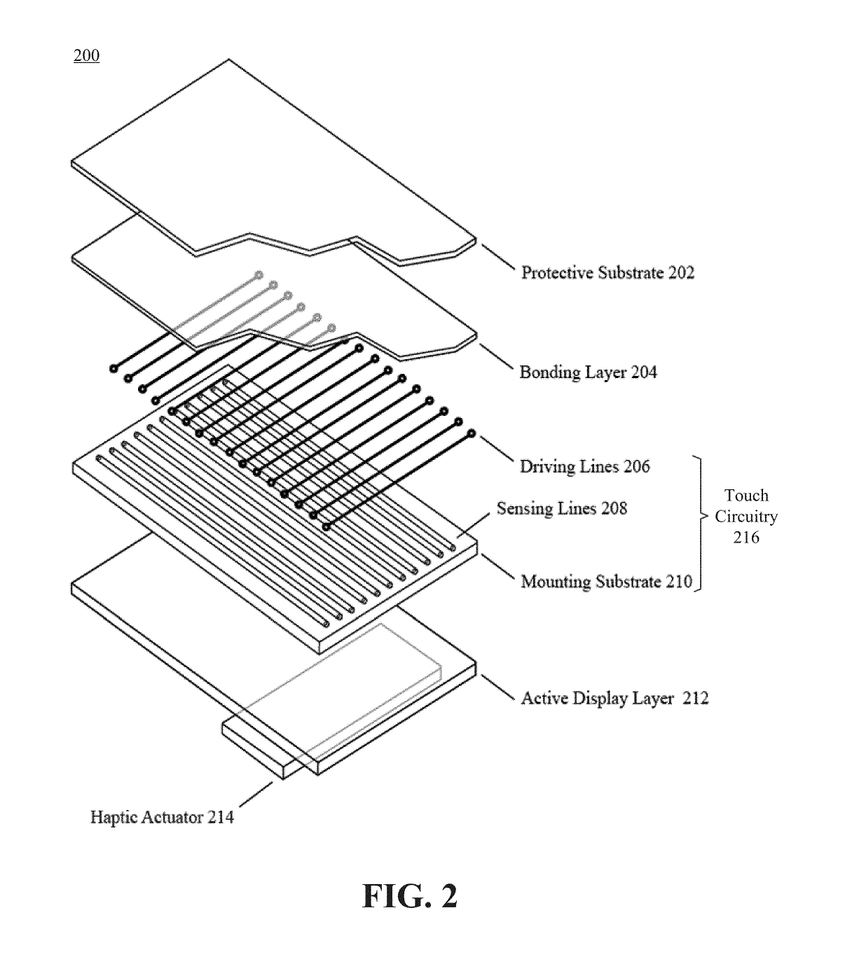

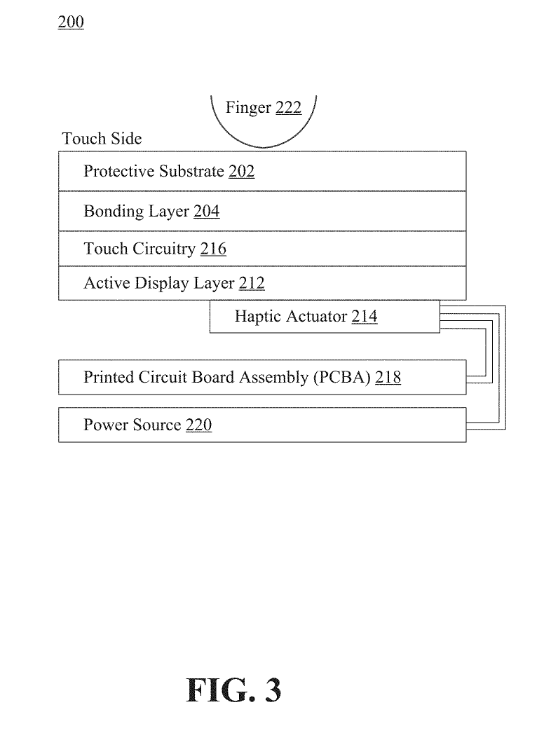

FIG. 2 is an exploded perspective view of a conventional display assembly 200 for a user device. FIG. 3, meanwhile, is a side view of a user device that illustrates how a haptic actuator 214 is conventionally disposed beneath a portion of the display assembly 200.

The display assembly 200 can include a protective substrate 202, an optically-clear bonding layer 204, driving lines 204 and sensing lines 208 disposed on a mounting substrate 210, and a display layer 212. Various embodiments can include some or all of these layers, as well as other layers (e.g., optically-clear adhesive layers).

The protective substrate 202 enables a user to interact with the display assembly 200 (e.g., by making contact with an outer surface using a finger 222). The protective substrate 202 is preferably substantially or entirely transparent and can be composed of glass, plastic, or any other suitable material (e.g., crystallized aluminum oxide).

Together, the driving lines 206 and sensing lines 208 include multiple electrodes (“nodes”) that create a coordinate grid for the display assembly 200. The coordinate grid may be used by a processor on a printed circuit board assembly (PCBA) 218 to determine the intent of a user interaction with the protective substrate 202. The driving lines 206 and/or sensing lines 208 can be mounted to or embedded within a transparent substrate 210, such as glass or plastic. The driving lines 206, sensing lines 208, and/or mounting substrate 210 are collectively referred to herein as “touch circuitry 216.”

An optically-clear bonding layer 204 may be used to bind the protective substrate 202 to the touch circuitry 216, which generates signals responsive to a user interaction with the protective substrate 202. The bonding layer 204 can include an acrylic-based or silicon-based adhesive, as well as one or more layers of indium-tin-oxide (ITO). Moreover, the bonding layer 204 is preferably substantially or entirely transparent (e.g., greater than 99% light transmission) and may display good adhesion to a variety of substrates, including glass, polyethylene (PET), polycarbonate (PC), polymethyl methacrylate (PMMA), etc.

A display layer 212 is configured to display content with which the user may be able to interact. The display layer 212 could include, for example, a liquid crystal display (LCD) panel and a backlight assembly (e.g., a diffuser and a backlight) that is able to illuminate the LCD panel. Other display technologies could also be used, such as light emitting diodes (LEDs), organic light emitting diodes (OLED), electrophoretic/electronic ink (“e-ink”), etc. Air gaps may be present between or within some of these layers. For example, an air gap may be present between the diffuser and the backlight in the backlight assembly.

As shown in FIGS. 2-3, a haptic actuator 214 is normally disposed within the housing of the user device beneath a portion of the display assembly 200. The haptic actuator 214 is typically coupled to the PCBA 218 that includes one or more components (e.g., processors) for determining and specifying which haptic event(s) should be performed by the haptic actuator 214. The haptic actuator 214 is also electrically coupled to a power source 220, such as a rechargeable battery that is disposed within the housing. Oftentimes, the power source 220 is electrically coupled to multiple components (e.g., the touch circuitry 216, display layer 212, haptic actuator 214, and/or the PCBA 218).

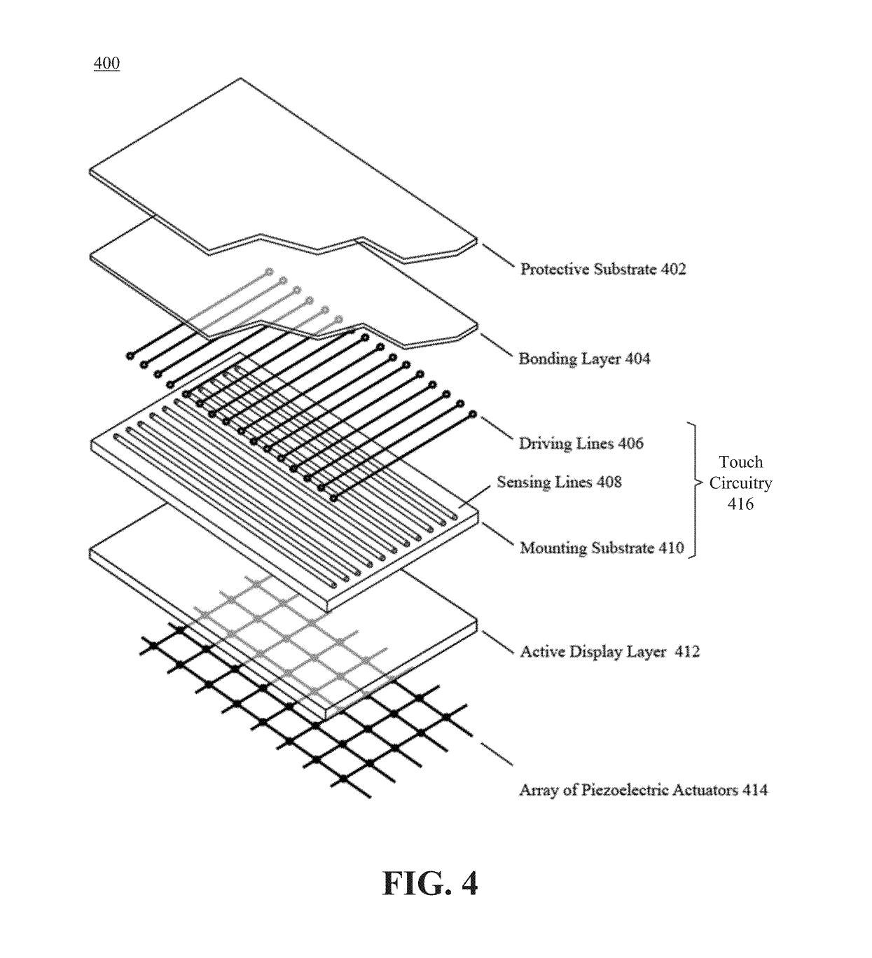

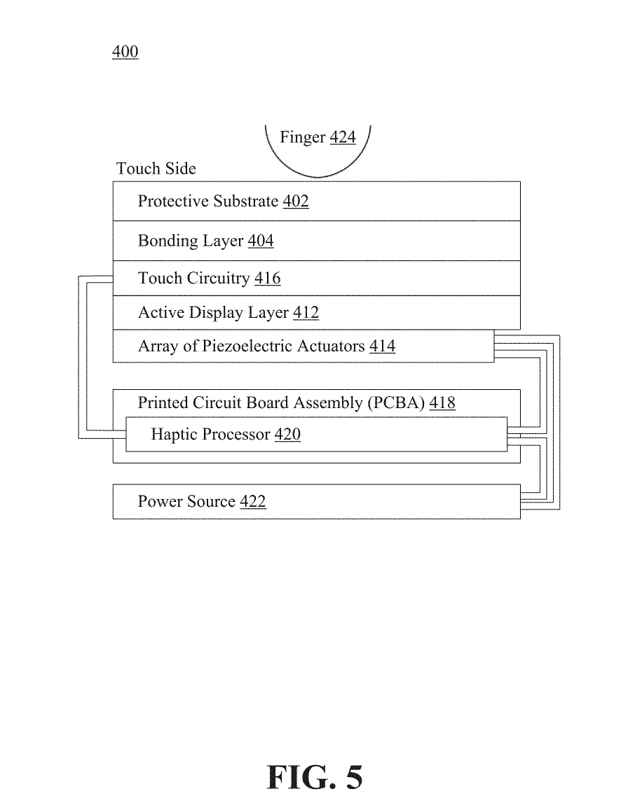

FIG. 4 is an exploded perspective view of a display assembly 400 for a user device that includes an array of piezoelectric actuators 414 capable of providing localized haptic feedback. FIG. 5, meanwhile, is a side view of a user device that illustrates how the array of piezoelectric actuators 414 can be disposed beneath some or all of the display assembly 400.

Similar to display assembly 200 of FIG. 2, the display assembly 400 can include a protective substrate 402, an optically-clear bonding layer 404, driving lines 406 and sensing lines 408 disposed on a mounting substrate 410 (i.e., touch circuitry 416), and a display layer 412. Various embodiments can include some or all of these layers, as well as other layers (e.g., optically-clear adhesive layers).

The protective substrate 402 enables a user to interact with the display assembly 400 (e.g., by making contact with an outer surface using a finger 424). The protective substrate 402 is preferably substantially or entirely transparent and can be composed of glass, plastic, or any other suitable material (e.g., crystallized aluminum oxide).

The touch circuitry 416 creates a coordinate grid for the display assembly 200 that may be used by a processor on a PCBA 418 to determine the intent of a user interaction with the protective substrate 402. In some embodiments, driving lines 406 and/or sensing lines 408 are mounted to or embedded within a transparent substrate 410, such as glass or plastic. In other embodiments, the touch circuitry 416 is connected to touch-sensing elements (e.g., capacitors) that are disposed between display elements (e.g., liquid crystals) in an integrated display panel that supports touch functionality. One skilled in the art will recognize that “touch circuitry” can be used to refer to different techniques/technologies for registering and analyzing touch events.

An optically-clear bonding layer 404 may be used to bind the protective substrate 402 to the touch circuitry 416. The bonding layer 404 can include an acrylic-based or silicon-based adhesive, as well as one or more layers of ITO. Moreover, the bonding layer 404 is preferably substantially or entirely transparent (e.g., greater than 99% light transmission) and may display good adhesion to a variety of substrates, including glass, polyethylene (PET), polycarbonate (PC), polymethyl methacrylate (PMMA), etc.

A display layer 412 is configured to display content with which the user may be able to interact. The display layer 412 could include, for example, a liquid crystal display (LCD) panel and a backlight assembly (e.g., a diffuser and a backlight) that is able to illuminate the LCD panel. However, as noted above, other display technologies could also be used, such as light emitting diodes (LEDs), organic light emitting diodes (OLED), electrophoretic/electronic ink (“e-ink”), etc.

An array of piezoelectric actuators 414 can be disposed beneath at least a portion of the display assembly 400. In some embodiments the piezoelectric actuators are integrated into the display assembly 400 (e.g., within an optically clear substrate), while in other embodiments the piezoelectric actuators are affixed to the inner side of the active display layer 412 (or some other layer in the display assembly 400). The piezoelectric actuators may be microceramic transducers that perform a haptic event (e.g., a tap or vibration) in response to having a voltage applied by a power source 422.

As shown in FIG. 4, the array can include multiple piezoelectric actuators that are arranged in a grid pattern. Other arrangements are also possible, such as lines or groupings of piezoelectric actuators. In some embodiments, each piezoelectric actuator in the array is individually coupled to the power source 422 and/or PCBA 418. These arrangements allow individual piezoelectric actuators to be induced into providing haptic events, which collectively provide localized haptic feedback. A PCBA 418 (and, more specifically, a haptic processor 420) can induce haptic events by specifying which one or more piezoelectric actuators should be subjected to an applied voltage. The piezoelectric actuator(s) could be chosen by the haptic processor 420 based on the coordinates, strength, or duration of the most recent touch event.

Although the array of piezoelectric actuators 414 is depicted as a grid in which each piezoelectric actuator is connected to its neighbors, other arrangements are also possible. For example, each piezoelectric actuator could be electrically coupled to the power source 422 and/or the haptic processor 420 so that the piezoelectric actuators are independently controllable. Such a configuration may also allow the piezoelectric actuators to simultaneously perform different haptic events. For example, the piezoelectric actuators near the bottom of the display assembly 400 could periodically vibrate, while the piezoelectric actuators near the top of the display assembly 400 could vibrate continuously. Similarly, each piezoelectric actuator in the array could vibrate at different intensities based on the distance between the corresponding piezoelectric actuator and the most recent touch event performed by a user.

The array of piezoelectric actuators 414 can also perform haptic events based on the digital content being shown by the display layer 412 at a given point in time. For example, some piezoelectric actuators may vibrate and others may remain still when the user interacts with an application by touching the protective substrate 402. The array of piezoelectric actuators 414 could also create a false sense of location by inducing certain piezoelectric actuators to perform haptic events.

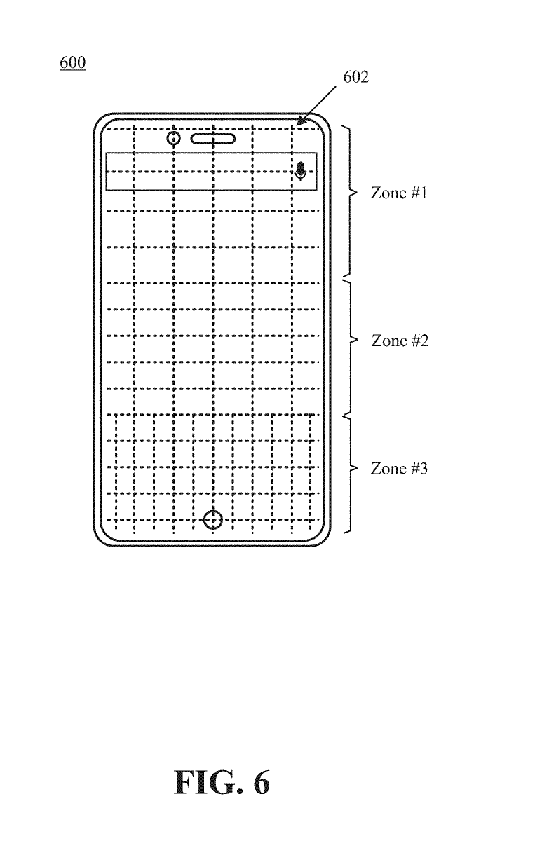

FIG. 6 depicts user device 600 that includes an array of piezoelectric actuators 602 having multiple zones with different actuator densities. Although the array of piezoelectric actuators 602 is depicted as a grid, other arrangements are also possible and, in some embodiments, may be preferred. Moreover, the array of piezoelectric actuators 602 could have one or more segments where no actuators are present. For example, a rectangular segment around the front-facing camera or the touch-sensitive button may be completely devoid of piezoelectric actuators.

In some embodiments, the array of piezoelectric actuators 602 is as wide and tall as the display itself. However, the array of piezoelectric actuators 602 need not always encompass the entire display. For example, the array of piezoelectric actuators may only extend across a subset of the display (e.g., only Zone #3), and the remainder of the display may be completely devoid of any piezoelectric actuators. The subset of the display may represent an area that is subject to frequent user interactions or an area that is expected to provide haptic feedback. For example, the array of piezoelectric actuators 602 may be positioned so that a piezoelectric actuator is aligned with each key of a keyboard shown on the display. As another example, piezoelectric actuators may be arranged around the outer edge of the display where a user is likely to grip the user device 600.

The piezoelectric actuators could be microceramic transducers that perform haptic events in response to receiving a voltage. For example, the piezoelectric actuators could comprise a synthetic piezoceramic material (e.g., barium titanate, lead zirconate titanate (PZT), or potassium niobate) or a lead-free piezoceramic material (e.g., sodium potassium niobate or bismuth ferrite). Other materials could also be used, such as quartz or carbon nanotubes that include piezoelectric fibers.

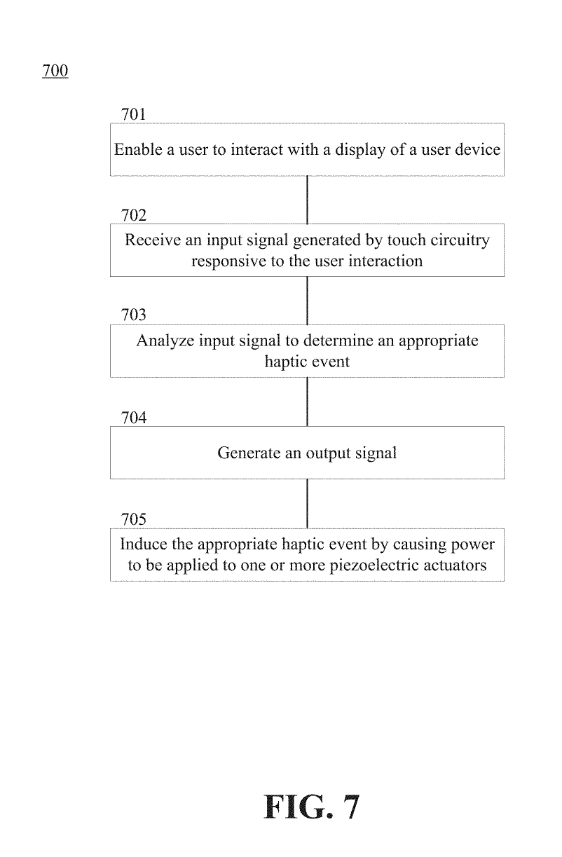

FIG. 7 depicts a process 700 for providing localized haptic feedback by a user device. The user device is initially provided to a user that includes an array of piezoelectric actuators disposed within or beneath a display assembly. The display assembly can include touch circuitry, which enables the user to interact directly with the outer surface of the display assembly (step 701). For example, the user may interact with digital content (e.g., an application or web browser) shown on the user device by touching the outer surface of the display assembly.

The touch circuitry can be configured to generate an input signal (also referred to as a “touch event signal”) in response to the user interacting with the display assembly. The input signal can then be transmitted from the touch circuitry to a haptic processor (step 702). One skilled in the art will recognize that the systems and techniques described herein can be implemented based on other types of input (e.g., those provided by input/output devices, such as mice and keyboards) or no input at all (e.g., haptic events may be automatically performed based on content that is to be shown by the user device).

The haptic processor can analyze the input signal to determine an appropriate haptic event to be performed by one or more of the piezoelectric actuators within the array (step 703). More specifically, the haptic processor may analyze the metadata of the input signal, which could specify the strength of the touch event, the location (i.e., coordinates) of the touch event, and other contextual information (e.g., a timestamp or a designation of the content that is being shown by the user device).

In some embodiments, the haptic processor determines the appropriate haptic event by reviewing instructions that are to be executed by the user device to identify an application programming interface (API) call to a certain haptic event. For example, the instructions/code for an application being executed by the user device may include tags for certain haptic events (e.g., perform haptic event of type A when the user interacts with point B at time C). These calls to certain haptic events may be inserted by a developer when the application is being developed or could be added later on (e.g., as a patch/update). In some embodiments, the developer must choose from a predetermined set of haptic events that can be performed by the array of piezoelectric actuators. In other embodiments, the developer of the content is able to create unique haptic events that can be performed by the array of piezoelectric actuators. Thus, developers may be able to convert content created for conventional user devices so that the content is usable with the user devices described herein. One skilled in the art will recognize that the same techniques can be used for applications, programs, scripts, etc.

When the appropriate haptic event has been identified, the haptic processor can generate an output signal that induces a power source to selectively apply a voltage to one or more of the piezoelectric actuators (step 704). The output signal may specify how much voltage is to be applied, how long the voltage is to be applied, which piezoelectric actuator(s) are to receive the voltage, etc.

Application of the voltage causes the piezoelectric actuator(s) to perform the appropriate haptic event (step 705). For example, a voltage could be applied to a single piezoelectric actuator or multiple piezoelectric actuators. Alternatively, different voltages could be applied to multiple piezoelectric actuators (and thereby induce haptic events of different types, strengths, etc.). Therefore, the appropriate haptic event may require that non-adjacent piezoelectric actuators simultaneously perform the same haptic event or different haptic events.

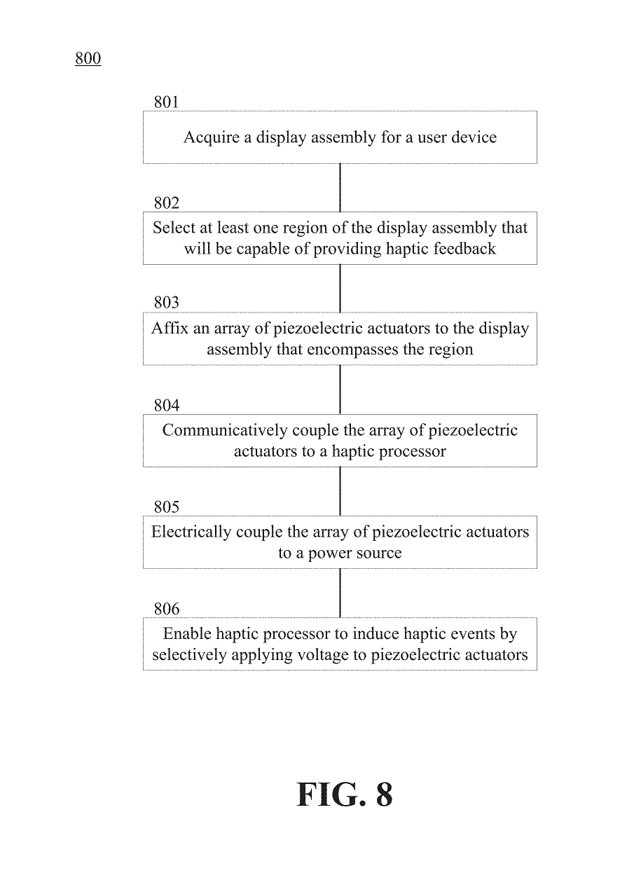

FIG. 8 depicts a process 800 for manufacturing a user device that includes an array of piezoelectric actuators, which are capable of providing localized haptic feedback. A display assembly for a user device is initially received by a manufacturer (step 801). The display assembly could be, for example, display assembly 400 of FIGS. 4-5. The display assembly typically includes a protective substrate, touch circuitry that generates signals responsive to user interactions with the protective substrate, and a display layer that presents digital content to a user.

The manufacturer can then select at least one region of the display assembly that will be able to provide localized haptic feedback (step 802). The region can be a subset of the display assembly or the entirety of the display assembly as shown in FIG. 6. The region may be selected because it represents an area that is subject to frequent user interactions or an area that is expected to provide haptic feedback. An array of piezoelectric actuators could be affixed to the region of the display assembly (step 803). The array typically includes multiple piezoelectric actuators that are individually controllable by a haptic processor.

The array of piezoelectric actuators is then communicatively coupled to the haptic processor (step 804) and electrically coupled to a power source (step 805). The power source could be, for example, a rechargeable lithium-ion (Li-Ion) battery, a rechargeable nickel-metal hydride (NiMH) battery, a rechargeable nickel-cadmium (NiCad) battery, or any other power source suitable for an electronic user device. Other types of power sources may also be used. For example, some user devices may be designed with the intention that they remain electrically coupled to a power source (e.g., an outlet) during use and therefore do not require batteries at all. The haptic processor induces haptic events by controlling how the power source applies voltages to the array of piezoelectric actuators. Thus, the arrangement and coupling of the components enables the haptic processor to produce localized haptic feedback by selectively causing voltages to be applied to one or more piezoelectric actuators within the array (step 806).

Unless contrary to physical possibility, it is envisioned that the steps described above may be performed in various sequences and combinations. For instance, the array of piezoelectric actuators could be integrated within the display assembly itself (and thus may not need to be affixed to the display assembly as described in step 803). Additional steps could also be included in some embodiments. For example, the haptic processor and/or power source could also be coupled to other components of the user device. As another example, the user device may be configured to invoke and execute an application that allows a user to manually modify whether the array of piezoelectric actuators will perform haptic events, which haptic event(s) may be performed, strength or duration of haptic events that are to be performed, etc.

### Processing System

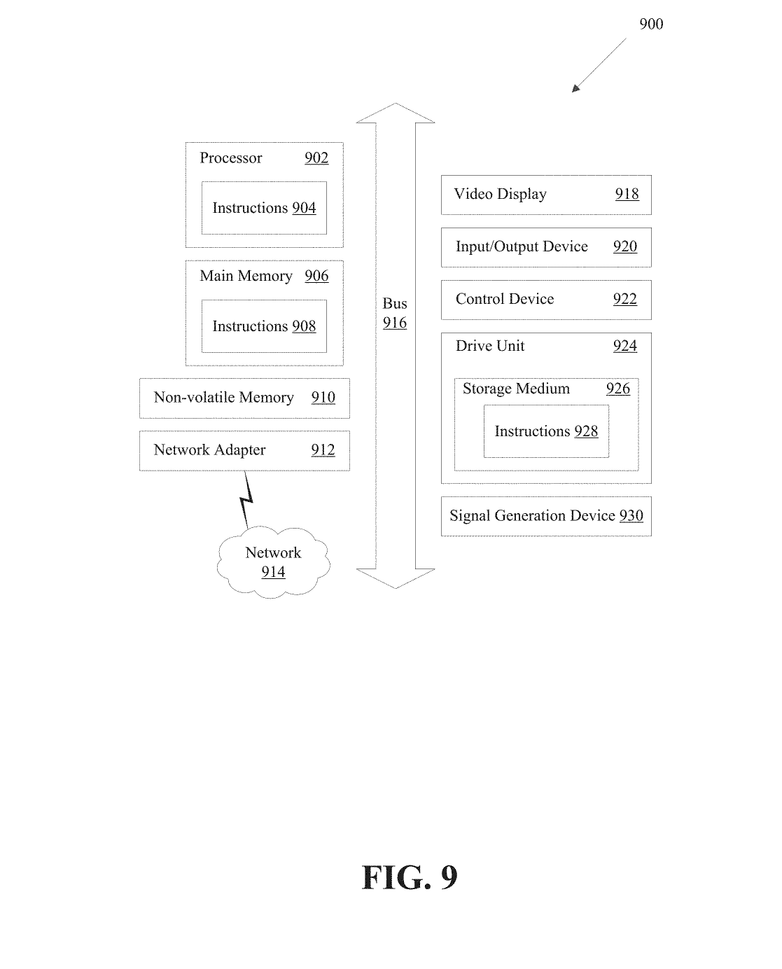

FIG. 9 is a block diagram illustrating an example of a processing system 900 in which at least some operations described herein can be implemented. The computing system may include one or more central processing units (“processors”) 902, main memory 906, non-volatile memory 910, network adapter 912 (e.g., network interfaces), video display 918, input/output devices 920, control device 922 (e.g., keyboard and pointing devices), drive unit 924 including a storage medium 926, and signal generation device 930 that are communicatively connected to a bus 916. The bus 916 is illustrated as an abstraction that represents any one or more separate physical buses, point to point connections, or both connected by appropriate bridges, adapters, or controllers. The bus 916, therefore, can include, for example, a system bus, a Peripheral Component Interconnect (PCI) bus or PCI-Express bus, a HyperTransport or industry standard architecture (ISA) bus, a small computer system interface (SCSI) bus, a universal serial bus (USB), IIC (I2C) bus, or an Institute of Electrical and Electronics Engineers (IEEE) standard 1394 bus, also called “Firewire.”

In various embodiments, the processing system 900 operates as part of a user device (e.g., user device 600 of FIG. 6), although the processing system 900 could also be connected (e.g., wired or wirelessly) to the user device. In a networked deployment, the processing system 900 may operate in the capacity of a server or a client machine in a client-server network environment, or as a peer machine in a peer-to-peer (or distributed) network environment.

The processing system 900 may be a server computer, a client computer, a personal computer (PC), a tablet PC, a laptop computer, a personal digital assistant (PDA), a mobile telephone, an iPhone®, an iPad®, a Blackberry®, a processor, a telephone, a web appliance, a network router, switch or bridge, a console, a hand-held console, a gaming device, a music player, or any portable, device or any machine capable of executing a set of instructions (sequential or otherwise) that specify actions to be taken by the processing system.

While the main memory 906, non-volatile memory 910, and storage medium 926 (also called a “machine-readable medium) are shown to be a single medium, the term “machine-readable medium” and “storage medium” should be taken to include a single medium or multiple media (e.g., a centralized or distributed database, and/or associated caches and servers) that store one or more sets of instructions 928. The term “machine-readable medium” and “storage medium” shall also be taken to include any medium that is capable of storing, encoding, or carrying a set of instructions for execution by the computing system and that cause the computing system to perform any one or more of the methodologies of the presently disclosed embodiments.

In general, the routines executed to implement the embodiments of the disclosure, may be implemented as part of an operating system or a specific application, component, program, object, module or sequence of instructions referred to as “computer programs.” The computer programs typically comprise one or more instructions (e.g., instructions 904, 908, 928) set at various times in various memory and storage devices in a computer, and that, when read and executed by one or more processing units or processors 902, cause the processing system 900 to perform operations to execute elements involving the various aspects of the disclosure.

Moreover, while embodiments have been described in the context of fully functioning computers and computer systems, those skilled in the art will appreciate that the various embodiments are capable of being distributed as a program product in a variety of forms, and that the disclosure applies equally regardless of the particular type of machine or computer-readable media used to actually effect the distribution.

Further examples of machine-readable storage media, machine-readable media, or computer-readable (storage) media include, but are not limited to, recordable type media such as volatile and non-volatile memory devices 910, floppy and other removable disks, hard disk drives, optical disks (e.g., Compact Disk Read-Only Memory (CD ROMS), Digital Versatile Disks (DVDs)), and transmission type media, such as digital and analog communication links.

The network adapter 912 enables the processing system 900 to mediate data in a network 914 with an entity that is external to the processing system 900 through any known and/or convenient communications protocol supported by the processing system 900 and the external entity. The network adapter 912 can include one or more of a network adaptor card, a wireless network interface card, a router, an access point, a wireless router, a switch, a multilayer switch, a protocol converter, a gateway, a bridge, bridge router, a hub, a digital media receiver, and/or a repeater.

The network adapter 912 can include a firewall which can, in some embodiments, govern and/or manage permission to access/proxy data in a computer network, and track varying levels of trust between different machines and/or applications. The firewall can be any number of modules having any combination of hardware and/or software components able to enforce a predetermined set of access rights between a particular set of machines and applications, machines and machines, and/or applications and applications, for example, to regulate the flow of traffic and resource sharing between these varying entities. The firewall may additionally manage and/or have access to an access control list which details permissions including for example, the access and operation rights of an object by an individual, a machine, and/or an application, and the circumstances under which the permission rights stand.

As indicated above, the techniques introduced here implemented by, for example, programmable circuitry (e.g., one or more microprocessors), programmed with software and/or firmware, entirely in special-purpose hardwired (i.e., non-programmable) circuitry, or in a combination or such forms. Special-purpose circuitry can be in the form of, for example, one or more application-specific integrated circuits (ASICs), programmable logic devices (PLDs), field-programmable gate arrays (FPGAs), etc.

### Remarks

The foregoing description of various embodiments has been provided for the purposes of illustration and description. It is not intended to be exhaustive or to limit the claimed subject matter to the precise forms disclosed. Many modifications and variations will be apparent to one skilled in the art. Embodiments were chosen and described in order to best describe the principles of the invention and its practical applications, thereby enabling others skilled in the relevant art to understand the claimed subject matter, the various embodiments, and the various modifications that are suited to the particular uses contemplated.

Although the above Detailed Description describes certain embodiments and the best mode contemplated, no matter how detailed the above appears in text, the embodiments can be practiced in many ways. Details of the systems and methods may vary considerably in their implementation details, while still being encompassed by the specification. As noted above, particular terminology used when describing certain features or aspects of various embodiments should not be taken to imply that the terminology is being redefined herein to be restricted to any specific characteristics, features, or aspects of the invention with which that terminology is associated. In general, the terms used in the following claims should not be construed to limit the invention to the specific embodiments disclosed in the specification, unless those terms are explicitly defined herein. Accordingly, the actual scope of the invention encompasses not only the disclosed embodiments, but also all equivalent ways of practicing or implementing the embodiments under the claims.

The language used in the specification has been principally selected for readability and instructional purposes, and it may not have been selected to delineate or circumscribe the inventive subject matter. It is therefore intended that the scope of the invention be limited not by this Detailed Description, but rather by any claims that issue on an application based hereon. Accordingly, the disclosure of various embodiments is intended to be illustrative, but not limiting, of the scope of the embodiments, which is set forth in the following claims.

1. A display assembly for a user device, the display assembly comprising:
a protective substrate;
touch circuitry located below the protective substrate that generates a signal responsive to a user interaction with the protective substrate;
a liquid crystal display (LCD) panel located below the touch circuitry;
a backlight assembly located below the LCD panel that generates light that illuminates the LCD panel; and
an array of piezoelectric actuators located below the backlight assembly,
wherein each of the piezoelectric actuators is electrically coupled to a power source, and
wherein each of the piezoelectric actuators is independently controllable to provide localized haptic feedback to certain regions of the display assembly.

2. The display assembly of claim 1, wherein the protective substrate is comprised of glass.

3. The display assembly of claim 1, further comprising a bonding adhesive layer disposed between the protective substrate and the touch circuitry.

4. The display assembly of claim 1, wherein the touch circuitry is affixed to a mounting substrate that is directly adjacent to the LCD panel.

5. The display assembly of claim 1, wherein each of the piezoelectric actuators is comprised of a ceramic material.

6. The display assembly of claim 1, wherein density of the piezoelectric actuators in the array varies across the display assembly.

7. The display assembly of claim 1, wherein the backlight assembly includes:
a diffuser configured to diffuse the light emitted toward the LCD panel, and
a backlight configured to generate the light that illuminates the LCD panel.

8. An electronic user device comprising:
a protective substrate disposed within a housing;
a display assembly located below the protective substrate, wherein the display assembly includes
touch circuitry that generates a signal responsive to a user interaction with the protective substrate,
a display panel, and
an array of piezoelectric actuators that are independently controllable and provide localized haptic feedback;
a power source that is disposed within the housing and electrically coupled to each of the piezoelectric actuators; and
a processor that is coupled to the touch circuitry and the power source,
wherein the processor is configured to selectively induce at least one of the piezoelectric actuators to perform a haptic event by causing the power source to apply a voltage to the at least one piezoelectric actuator.

9. The electronic user device of claim 8, wherein the array of piezoelectric actuators are embedded within an optically-clear substrate layer below the display panel.

10. The electronic user device of claim 8, wherein each of the piezoelectric actuators is comprised of Lead Zirconate Titanate (PZT).

11. The electronic user device of claim 8, wherein the array of piezoelectric actuators is able to perform multiple haptic events simultaneously.

12. The electronic user device of claim 11, wherein the multiple haptic events include haptic events of different types, durations, or intensities.

13. The electronic user device of 8, wherein the array of piezoelectric actuators extends across a subset of the display assembly that is subject to frequent user interactions.

14. The electronic user device of claim 13, wherein the subset of the display assembly corresponds to where the display assembly presents a keyboard.

15. The electronic user device of claim 14, wherein each of the piezoelectric actuators corresponds to an individual key of the keyboard, and wherein each of the piezoelectric actuators is configured to perform a haptic event in response to a user interacting with the corresponding key.

16. A method comprising:
enabling a user to interact with a protective substrate that covers a display assembly of a user device;
receiving an input signal that is generated by touch circuitry responsive to a user interaction with the protective substrate,
wherein the input signal includes metadata regarding characteristics of the user interaction;
analyzing the metadata of the input signal to determine an appropriate haptic event to be performed by the user device;
generating an output signal and transmitting the output signal to a power source; and
inducing the appropriate haptic event by causing the power source to selectively provide power to at least one piezoelectric actuator in an array of piezoelectric actuators that is disposed below the display assembly of the user device.

17. The method of claim 16, wherein the metadata includes touch event coordinates, touch event strength, or both.

18. The method of claim 16, wherein analyzing the metadata of the input signal to determine the appropriate haptic event further comprises:
reviewing instructions to be executed by a processor of the user device to identify an API call to the appropriate haptic event.

19. The method of claim 18, wherein the appropriate haptic event is one of a predetermined set of haptic events that can be performed by the array of piezoelectric actuators.

20. The method of claim 16, wherein the appropriate haptic event requires that multiple non-adjacent piezoelectric actuators in the array simultaneously perform haptic events.

21. The method of claim 20, wherein the simultaneous haptic events are different types of haptic events.

22. The method of claim 16, wherein the piezoelectric actuators in the array are arranged in a grid pattern.

23. An electronic user device capable of providing localized haptic feedback, the electronic user device comprising:
a protective substrate;
a display assembly located below the protective substrate, wherein the display assembly includes
touch circuitry that generates a signal responsive to a user interaction with the protective substrate,
a display panel that presents digital content to a user, and
an array of piezoelectric actuators that are able to independently perform different types of haptic events;
a power supply;
a processor; and
a memory that includes instructions for inducing haptic events, wherein the instructions cause the processor to:
receive an input signal that is generated by the touch circuitry responsive to a user interaction with the protective substrate;
analyze the input signal to identify an appropriate haptic event to be performed by at least one of the piezoelectric actuators; and
generate an output signal that causes the power source to selectively provide power to the at least one piezoelectric actuator, which causes the at least one piezoelectric actuator to perform the appropriate haptic event.

24. The electronic user device of claim 23, wherein the power supply is electrically coupled to the touch circuitry, the display panel, the array of piezoelectric actuators, and the processor.

25. The electronic user device of claim 23, wherein the array of piezoelectric actuators extends across substantially all of the display assembly.

26. The electronic user device of claim 23, wherein the array of piezoelectric actuators extends across a subset of the display assembly.

27. The electronic user device of claim 26, wherein the subset of the display panel represents an area that is subject to frequent user interactions or an area that is expected to provide haptic feedback.
